(19) United States
(12) Patent Application Publication
(10) Pub. No.: US 2024/0287408 A1
(43) Pub. Date: Aug. 29, 2024

(54) TREATMENT SOLUTION FOR SEMICONDUCTOR SUBSTRATES

(71) Applicant: FUJIFILM Corporation, Tokyo (JP)

(72) Inventors: Tetsuya KAMIMURA, Shizuoka (JP); Naoko OUCHI, Haibara-gun (JP); Shimpei YAMADA, Haibara-gun (JP)

(73) Assignee: FUJIFILM Corporation, Tokyo (JP)

(21) Appl. No.: 18/647,489

(22) Filed: Apr. 26, 2024

Related U.S. Application Data
(63) Continuation of application No. PCT/JP2022/037273, filed on Oct. 5, 2022.

(30) Foreign Application Priority Data
Oct. 29, 2021 (JP) 2021-177094

(51) Int. Cl. C11D 1/90; C11D 3/20; C11D 3/24; C11D 3/30; C11D 3/34; C11D 3/48

(52) U.S. Cl. CPC C11D 1/90; C11D 3/2034; C11D 3/2044; C11D 3/2079; C11D 3/2082; C11D 3/2086; C11D 3/24; C11D 3/30; C11D 3/3481; C11D 3/48

(57) ABSTRACT

An object of the present invention is to provide a treatment liquid for a semiconductor substrate, which has excellent storage stability, excellent anticorrosion properties of tungsten, and excellent cleanability for a semiconductor substrate having tungsten after a CMP treatment. The treatment liquid for a semiconductor substrate according to an embodiment of the present invention includes an amphoteric compound, an antimicrobial agent, and an amino alcohol, in which the amphoteric compound includes an acid group having a pKa of less than 4.5 and a basic group having a pKa of more than 4.5, and the number of the basic groups is larger than the number of the acid groups.

### CROSS-REFERENCE TO RELATED APPLICATIONS

This application is a Continuation of PCT International Application No. PCT/JP2022/037273 filed on Oct. 5, 2022, which claims priority under 35 U.S.C. § 119(a) to Japanese Patent Application No. 2021-177094 filed on Oct. 29, 2021. The above applications are hereby expressly incorporated by reference, in their entirety, into the present application.

### BACKGROUND OF THE INVENTION

### 1. Field of the Invention

The present invention relates to a treatment liquid for a semiconductor substrate.

### 2. Description of the Related Art

Semiconductor elements such as a charge-coupled device (CCD) and a memory are manufactured by forming a fine electronic circuit pattern on a substrate, using a photolithographic technique. Specifically, the semiconductor elements are manufactured by forming a resist film on a laminate which has a metal film serving as a wiring line material, an etching stop layer, and an interlayer insulating layer on a substrate, and carrying out a photolithography step and a dry etching step (for example, a plasma etching treatment).

In the manufacture of a semiconductor element, a chemical mechanical polishing (CMP) treatment in which a surface of a semiconductor substrate having a metal wiring line film, a barrier metal, an insulating film, or the like is flattened using a polishing slurry containing polishing fine particles (for example, silica and alumina) or the like may be carried out. In the CMP treatment, polishing fine particles to be used in the CMP treatment, a polished wiring line metal film and/or residues such as a metal component derived from a barrier metal and the like easily remain on a surface of a semiconductor substrate after the CMP treatment.

Since these residues can short-circuit between wiring lines and adversely affect the electrical characteristics of a semiconductor, a cleaning step in which these residues are removed from a surface of the semiconductor substrate is generally performed.

For example, JP2020-188090A discloses “a semiconductor cleaning or chemical mechanical polishing composition for treating a substrate including cobalt, in which the composition contains the following (A-1) component, and contains at least one selected from the group consisting of the following (A-2) component and the following components (A-3) and the following component (B); and at least one selected from the group consisting of (A-1) glutamic acid, (A-2) histidine, (A-3) cysteine, and (B) an inorganic acid and a salt thereof”.

### SUMMARY OF THE INVENTION

The present inventors have studied the treatment liquid for a semiconductor substrate described in JP2020-188090A and the like, and have thus found that at least one of (1) storage stability, (2) anticorrosion properties of tungsten, and (3) cleanability for a semiconductor substrate having tungsten after a CMP treatment is poor.

Furthermore, the storage stability means that in a case where a treatment liquid for a semiconductor substrate is stored, generation of molds and bacteria in the treatment liquid can be suppressed.

Therefore, an object of the present invention is to provide a treatment liquid for a semiconductor substrate, which has excellent storage stability, excellent anticorrosion properties of tungsten, and excellent cleanability for a semiconductor substrate having tungsten after a CMP treatment.

The present inventors have found that the object can be accomplished by the following configurations.
[1] A treatment liquid for a semiconductor substrate, including:
   an amphoteric compound;
   an antimicrobial agent; and
   an amino alcohol,
   in which the amphoteric compound includes an acid group having a pKa of less than 4.5 and a basic group having a pKa of more than 4.5, and
   the number of the basic groups is larger than the number of the acid groups.
[2] The treatment liquid for a semiconductor substrate according to [1],
   in which the amphoteric compound includes a basic amino acid.
[3] The treatment liquid for a semiconductor substrate according to [1] or [2],
   in which the antimicrobial agent includes at least one or more antimicrobial agents selected from the group consisting of a cationic antimicrobial agent, a carboxylic acid-based antimicrobial agent, a phenolic antimicrobial agent, an isothiazoline-based antimicrobial agent, and an alcoholic antimicrobial agent.
[4] The treatment liquid for a semiconductor substrate according to any one of [1] to [3], further including an organic acid.
[5] The treatment liquid for a semiconductor substrate according to any one of [1] to [4]
   in which a pH of the treatment liquid is 4.0 to 8.0.
[6] The treatment liquid for a semiconductor substrate according to any one of [1] to [5]
   in which a mass ratio of a content of the amphoteric compound to a content of the antimicrobial agent is 3.00 to 50.00.
[7] The treatment liquid for a semiconductor substrate according to any one of [1] to [6],
   in which a mass ratio of a content of the amino alcohol to a content of the antimicrobial agent is 10.00 to 150.00.
[8] The treatment liquid for a semiconductor substrate according to any one of [1] to [7],
   in which the treatment liquid for a semiconductor substrate is used for cleaning a semiconductor substrate having tungsten, which has been subjected to a chemical mechanical polishing treatment.

According to the present invention, it is possible to provide a treatment liquid for a semiconductor substrate, which has excellent storage stability, excellent anticorrosion properties of tungsten, and excellent cleanability for a semiconductor substrate having tungsten after a CMP treatment.

### DESCRIPTION OF THE PREFERRED EMBODIMENTS

Hereinafter, an example of a form for carrying out the present invention will be described.

In the present specification, a numerical value range expressed using “to” means a range that includes the preceding and succeeding numerical values of “to” as the lower limit value and the upper limit value, respectively.

In the present specification, in a case where two or more kinds of a certain component are present, the “content” of the component means a total content of the two or more kinds of the component.

Unless otherwise specified, compounds described in the present specification may include structural isomers, optical isomers, and isotopes. In addition, one kind of structural isomer, optical isomer, and isotope may be included, or two or more kinds thereof may be included.

In the present specification, psi means pound-force per square inch, where 1 psi=6,894.76 Pa.

In the present specification, “ppm” means “parts-per-million (10-6)” and “ppb” means “parts-per-billion (10-9)”.

In the present specification, unless otherwise specified, a weight-average molecular weight (Mw) and a number-average molecular weight (Mn) are values converted using polystyrene as a standard substance, as measured by a gel permeation chromatography (GPC) analysis apparatus, using TSKgel GMHxL, TSKgel G4000HxL, or TSKgel G2000HxL (all product names manufactured by Tosoh Corporation) as a column, tetrahydrofuran as an eluent, a differential refractometer as a detector, and polystyrene as a standard substance.

In the present specification, unless otherwise specified, a molecular weight of a compound having a molecular weight distribution is the weight-average molecular weight.

In the present specification, “total mass of the components excluding the solvent in the treatment liquid” means the total content of all components included in the treatment liquid other than a solvent such as water and an organic solvent.

### [Treatment Liquid for Semiconductor Substrate]

A treatment liquid for a semiconductor substrate (hereinafter also referred to as a “treatment liquid”) of an embodiment of the present invention includes an amphoteric compound (hereinafter also referred to as a “specific compound”), an antimicrobial agent, and an amino alcohol, in which the amphoteric compound includes an acid group having a pKa of less than 4.5 and a basic group having a pKa of more than 4.5, and the number of the basic groups is larger than the number of the acid groups.

A mechanism by which the object of the present invention is accomplished by the configurations is not clear, but is presumed that the various components act in a cooperative manner, making it possible to obtain a desired effect. In particular, it is presumed that the specific compound contributes to the anticorrosion properties of tungsten, the antimicrobial agent contributes to the storage stability, and the amino alcohol contributes to the anticorrosion properties of tungsten. In addition, it is considered that a combination of the specific compound and the amino alcohol makes it possible to form a protective film on a surface of tungsten in a concerted manner, which also contributes to the anticorrosion properties of tungsten.

Hereinafter, the expression that at least one effect of the storage stability, the anticorrosion properties of tungsten, or the cleanability for a semiconductor substrate having tungsten after a CMP treatment is more excellent is also referred to as being that “the effects of the present invention are more excellent”.

Hereinafter, various components that can be included in the treatment liquid will be described in detail.

### [Specific Compound]

The treatment liquid includes a specific compound.

The specific compound is a compound including an acid group having a pKa of less than 4.5 and a basic group having a pKa of more than 4.5, in which the number of the basic groups is larger than the number of the acid groups.

The specific compound may be in a form of a salt (for example, a known salt).

The specific compound has an acid group having a pKa of less than 4.5.

The pKa of the acid group is less than 4.5, preferably 4.0 or less, more preferably 3.5 or less, and still more preferably 3.0 or less. A lower limit thereof is preferably 1.0 or more, and more preferably 1.5 or more.

In a case where the one acid group has a plurality of pKa's, the lowest pKa among the plurality of pKa's may be less than 4.5. Specifically, in a case where the one acid group has, for example, three pKa's of a first pKa of 1, a second pKa of 5, and a third pKa of 10, the lowest first pKa is less than 4.5. Therefore, it corresponds to the acid group.

In a case where the specific compound has a plurality of acid groups, the specific compound has an acid group having a pKa of less than 4.5, and in a case where the number of the basic groups having a pKa of more than 4.5 is larger than the number of the acid groups having a pKa of less than 4.5, the specific compound may further have an acid group having a pKa of 4.5 or more.

The pKa of the acid group is a value in water (temperature: 25° C.) calculated using Calculator plugins (manufactured by Fujitsu Co., Ltd.). Furthermore, in a case where the measurement is not possible in the water, a value calculated in dimethyl sulfoxide is used.

Examples of the acid group include e a carboxy group, a thiol group, a sulfo group, a sulfonamide group, a phosphonic acid group, a sulfonylimide group, and a phenolic hydroxyl group, and the carboxy group is preferable.

The specific compound has a basic group having a pKa of more than 4.5.

The pKa of the basic group is more than 4.5, preferably 5.0 or more, more preferably 6.0 or more, and still more preferably 7.0 or more. An upper limit thereof is preferably 13.0 or less, and more preferably 12.5 or less.

In a case where the one basic group included in the specific compound has a plurality of pKa's, it is sufficient that the highest pKa among the plurality of pKa's is more than 4.5. Specifically, in a case where the basic group has three pKa's of a first pKa of 1, a second pKa of 4, and a third pKa of 10, the highest third pKa is more than 4.5. Therefore, this group corresponds to the basic group.

In addition, in a case where the specific compound has a plurality of basic groups, the specific compound has a basic group having a pKa of more than 4.5, and in a case where the number of the basic groups having a pKa of more than 4.5 is larger than the number of the acid groups having a pKa of less than 4.5, the specific compound may further have a basic group having a pKa of 4.5 or less.

The pKa of the basic group can be calculated according to the same measuring method as that for the pKa of the acid group. Furthermore, the pKa of the basic group represents a pKa of a conjugate acid of the basic group.

Examples of the basic group include a basic group having a nitrogen atom, and specifically include a primary amino group (—NH₂), a secondary amino group (>NH) such as a guanidine group, a tertiary amino group (>N—), a quaternary ammonium base, and a heterocyclic group having a nitrogen atom as a ring member atom. Furthermore, in a case where the secondary amino group, the tertiary amino group, and the quaternary ammonium salt group constitute a ring member atom, they are classified into heterocyclic groups having a nitrogen atom as a ring member atom, and in a case where the groups have amino groups of different classes, they are classified into the highest amino group.

The heterocyclic group having a nitrogen atom as a ring member atom may be any of an aliphatic heterocyclic group having a nitrogen atom as a ring member atom or an aromatic heterocyclic group having a nitrogen atom as a ring member atom. Examples of the heterocyclic group include aliphatic heterocyclic groups such as a pyrrolidine ring group and a piperidine ring group, and aromatic heterocyclic groups such as a pyridine ring group, an imidazole ring group, and an indole ring group.

The basic group preferably includes at least one group selected from the group consisting of a primary amino group, a secondary amino group, a tertiary amino group, a quaternary ammonium base, and a heterocyclic group having a nitrogen atom as a ring member atom, and more preferably includes at least one group selected from the group consisting of the primary amino group, the secondary amino group, and the heterocyclic group having a nitrogen atom as a ring member atom.

The number of the basic groups having a pKa of more than 4.5 is larger than the number of the acid groups having a pKa of less than 4.5.

Specifically, a value obtained by subtracting the number of the acid groups from the number of the basic groups (the number of the basic groups−the number of the acid groups) is 1 or more, preferably 1 to 5, and more preferably 1 or 2.

The number of the acid groups is 1 or more, preferably 1 to 10, more preferably 1 to 3, and still more preferably 1.

The number of the basic groups is 2 or more, preferably 2 to 11, more preferably 2 to 4, and still more preferably 2.

The specific compound preferably includes a basic amino acid, more preferably includes at least one compound selected from the group consisting of arginine, histidine, lysine, ornithine, 2,4-diaminobutyric acid, tryptophan, asparagine, and glutamine, still more preferably includes at least one compound selected from the group consisting of arginine, histidine, lysine, ornithine, and 2,4-diaminobutyric acid, even still more preferably includes at least one compound selected from the group consisting of arginine, histidine, and lysine, and particularly more preferably includes arginine.

The specific compound may be used alone or in combination of two or more kinds thereof, and is preferably used in combination of two or more kinds (for example, two kinds) thereof.

A content of the specific compound is often 0.01% to 70.0% by mass, preferably 0.2% to 70.0% by mass, more preferably 1.0% to 50.0% by weight, still more preferably 3.0% to 40.0% by weight, and particularly preferably 5.0% to 20.0% by weight with respect to a total mass of the components excluding the solvent in the treatment liquid.

### [Antimicrobial Agent]

The treatment liquid includes an antimicrobial agent.

The antimicrobial agent is a compound having an antibacterial action against bacteria and/or an antifungal action against molds, and is a compound different from the above-mentioned specific compound and various components which will be described later.

The antimicrobial agent may be in a form of a salt (for example, a known salt).

Examples of the antimicrobial agent include a cationic antimicrobial agent (an antimicrobial agent having a cationic structure), a carboxylic acid-based antimicrobial agent (an antimicrobial agent having a carboxy group), a phenolic antimicrobial agent (an antimicrobial agent having a phenolic hydroxyl group), an isothiazoline-based antimicrobial agent (an antimicrobial agent having an isothiazoline structure), an alcoholic antimicrobial agent (an antimicrobial agent having a hydroxyl group), peracetic acid, and hydrogen peroxide. Furthermore, the antimicrobial agent having a carboxy group and the phenolic hydroxyl group is classified into the carboxylic acid-based antimicrobial agents.

Examples of the cationic antimicrobial agent include benzalkonium chloride, benzethonium chloride, and domiphen bromide, and benzethonium chloride is preferable.

Examples of the carboxylic acid-based antimicrobial agent include unsaturated carboxylic acids such as sorbic acid, aromatic carboxylic acids such as benzoic acid and salicylic acid, and sorbic acid, benzoic acid, or salicylic acid is preferable.

Examples of the phenolic antimicrobial agent include cresol, chlorothymol, dichloroxylenol, and hexachlorophene.

Examples of the isothiazoline-based antimicrobial agent include methylchloroisothiazolinone and methylisothiazolinone.

Examples of the alcoholic antimicrobial agent include phenoxyethanol, 1,2-pentanediol, and 1,2-hexanediol.

The antimicrobial agent preferably includes at least one antimicrobial agent selected from the group consisting of a cationic antimicrobial agent, a carboxylic acid-based antimicrobial agent, a phenolic antimicrobial agent, an isothiazoline-based antimicrobial agent, and an alcoholic antimicrobial agent, more preferably includes at least one antimicrobial agent selected from the group consisting of benzethonium chloride, the carboxylic acid-based antimicrobial agent, and the isothiazoline-based antimicrobial agent, and still more preferably includes at least one antimicrobial agent selected from the group consisting of benzethonium chloride, salicylic acid, benzoic acid, sorbic acid, methylchloroisothiazolinone, and methylisothiazolinone.

The antimicrobial agent may be used alone or in combination of two or more kinds thereof, and is preferably used in combination of two or more kinds (for example, two kinds) thereof.

A content of the antimicrobial agent is preferably 0.01% to 30.0% by mass, preferably 0.05% to 12.0% by mass, more preferably 0.1% to 10.0% by mass, and particularly preferably 0.2% to 5.0% by mass with respect to the total mass of the components excluding the solvent in the treatment liquid.

### [Amino Alcohol]

The amino alcohol is a compound having one or more amino groups selected from a primary amino group, a secondary amino group, and a tertiary amino group, and one or more hydroxyl groups.

The amino alcohol is a compound different from the above-mentioned various components.

Examples of the amino alcohol include a primary amino alcohol, a secondary amino alcohol, and a tertiary amino alcohol. Furthermore, in a case where the compound has amino groups of different classes, it is classified into the highest amino alcohol.

Examples of the primary amino alcohol include tris(hydroxymethyl)aminomethane (Tris), monoethanolamine (MEA), 2-amino-1,3-propanediol, 3-amino-1,2-propanediol, 1,3-diamino-2-propanol, 2-amino-2-methyl-1-propanol (AMP), 3-amino-1-propanol, 1-amino-2-propanol, diethylene glycolamine (DEGA), and 2-(aminoethoxy)ethanol (AEE).

Examples of the secondary amino alcohol include 1,3-bis[tris(hydroxymethyl)methylamino]propane, uracil, N-methylethanolamine, 2-(ethylamino)ethanol, 2-[(hydroxymethyl)amino]ethanol, 2-(propylamino)ethanol, N,N′-bis(2-hydroxyethyl)ethylenediamine, diethanolamine, 2-(2-aminoethylamino)ethanol (AAE), N-butylethanolamine, and N-cyclohexylethanolamine.

Examples of the tertiary amino alcohol include bis(2-hydroxyethyl)aminotris(hydroxymethyl)methane (Bis-Tris-Propane), N-methyldiethanolamine (MDEA), 2-(dimethylamino)ethanol (DMAE), N-ethyldiethanolamine (EDEA), 2-diethylaminoethanol, 2-(dibutylamino)ethanol, 2-[2-(dimethylamino)ethoxy]ethanol, 2-[2-(diethylamino)ethoxy]ethanol, triethanolamine, N-butyldiethanolamine (BDEA), N-tert-butyldiethanolamine (t-BDEA), 1-[bis(2-hydroxyethyl)amino]-2-propanol (Bis-HEAP), 1-(2-hydroxyethyl)piperazine (HEP), 1,4-bis(2-hydroxyethyl)piperazine (BHEP), 2-(N-ethylanilino)ethanol, N-phenyldiethanolamine (Ph-DEA), N-benzyldiethanolamine, p-tolyldiethanolamine, m-tolyldiethanolamine, 2-(dimethylamino)-1,3-propanediol, 2-[2-(dimethylamino)ethyl]methylamino]ethanol, and stearyldiethanolamine.

It is also preferable that the amino alcohol includes an amino alcohol having a quaternary carbon atom. The amino alcohol may have one or two or more quaternary carbon atoms.

Examples of the amino alcohol having a quaternary carbon atom include Tris, Bis-Tris, and Bis-Tris-Propane.

The amino alcohol preferably includes at least one compound selected from the group consisting of Tris, MEA, Bis-Tris, Bis-Tris-Propane, 2-amino-1,3-propanediol, 3-amino-1,2-propanediol, 1,3-diamino-2-propanol, and MDEA, more preferably includes at least one compound selected from the group consisting of Tris, Bis-Tris, Bis-Tris-Propane, 2-amino-1,3-propanediol, and 3-amino-1,2-propanediol, and still more preferably includes at least one compound selected from the group consisting of Tris, Bis-Tris, and Bis-Tris-Propane.

The amino alcohol may be used alone or in combination of two or more kinds thereof, and is preferably used in combination of two or more kinds (for example, two kinds) thereof.

A content of the amino alcohol is preferably 0.01% to 80.0% by mass, more preferably 2.0% to 72.0% by mass, still more preferably 5.0% to 68.0% by mass, and particularly preferably 10.0% to 60.0% by mass with respect to the total mass of the components excluding the solvent in the treatment liquid.

### [Content Ratios of Various Components]

A mass ratio of the content of the specific compound to the content of the antimicrobial agent (the content of the specific compound/the content of the antimicrobial agent) is often 0.10 to 1,000.00, preferably 1.00 to 60.00, more preferably 2.00 to 55.00, still more preferably 3.00 to 50.00, and particularly preferably 3.00 to 30.00.

A mass ratio of the content of the amino alcohol to the content of the antimicrobial agent (the content of the amino alcohol/the content of the antimicrobial agent) is often 1.00 to 4,000.00, preferably 4.00 to 180.00, and more preferably 10.00 to 150.00.

A mass ratio of the content of the specific compound to the content of the amino alcohol (the content of the specific compound/the content of the amino alcohol) is often 0.01 to 20.00, preferably 0.10 to 6.00, more preferably 0.12 to 4.00, and still more preferably 0.20 to 2.00.

### [Organic Acid]

The treatment liquid may include an organic acid.

The organic acid is a compound different from the above-mentioned various components. Examples thereof include an organic acid having neither an antibacterial action against bacteria nor an antifungal action against molds.

Examples of the organic acid include carboxylic acid-based organic acids such as an aliphatic carboxylic acid-based organic acid and an aromatic carboxylic acid-based organic acid, and phosphonic acid-based organic acids, the carboxylic acid-based organic acids are preferable, a dicarboxylic acid, an acid or a tricarboxylic acid is more preferable, and the tricarboxylic acid is still more preferable.

The organic acid may be in a form of salt. Examples of the salt include a sodium salt, a potassium salt, an ammonium salt, and an organic amine salt.

The carboxylic acid-based organic acid is a compound having one or two or more carboxy groups.

The carboxylic acid-based organic acid may further have a hydroxyl group as a functional group other than the carboxy group.

The number of the carboxy groups contained in the carboxylic acid-based organic acid is preferably 1 to 10, more preferably 2 to 10, and still more preferably 3 to 5.

Examples of the aliphatic carboxylic acid-based organic acid include oxalic acid, malonic acid, succinic acid, glutaric acid, adipic acid, pimelic acid, sebacic acid, maleic acid, malic acid, citric acid, tartaric acid, glycolic acid, and gluconic acid; and citric acid, malic acid, tartaric acid, or oxalic acid is preferable, and citric acid is more preferable.

Examples of the aromatic carboxylic acid-based organic acid include phthalic acid, isophthalic acid, terephthalic acid, gallic acid, trimellitic acid, mellitic acid, and cinnamic acid, and trimellitic acid is preferable.

Examples of the phosphonic acid-based organic acid include the compounds described in paragraphs [0026] to [0036] of WO2018/020878A and the compounds described in paragraphs [0031] to [0046] of WO2018/030006A, the content of which is incorporated herein by reference.

The organic acid preferably includes at least one organic acid selected from the group consisting of citric acid, glycolic acid, malic acid, tartaric acid, gluconic acid, oxalic acid, and trimellitic acid, more preferably includes at least one organic acid selected from the group consisting of citric acid, malic acid, tartaric acid, and oxalic acid, and still more preferably includes citric acid.

The organic acid may be used alone or in combination of two or more kinds thereof.

A content of the organic acid is preferably 5.0% to 98.0% by mass, more preferably 10.0% to 60.0% by mass, and still more preferably 15.0% to 50.0% by mass with respect to the total mass of the components excluding the solvent in the treatment liquid.

### [Polymer]

The treatment liquid may include a polymer.

The polymer is preferably a water-soluble polymer.

The “water-soluble polymer” means a polymer having two or more constitutional units linked in a linear or mesh form through a covalent bond, in which a mass of the polymer dissolved in 100 g of water at 20° C. is 0.1 g or more.

Examples of the water-soluble polymer include a polyacrylic acid, a polymethacrylic acid, a polymaleic acid, a polyvinylsulfonic acid, and salts thereof; copolymers of monomers such as styrene, α-methylstyrene, and/or 4-methylstyrene and acid monomers such as a (meth)acrylic acid and/or a maleic acid, and salts thereof; polyglycerin; vinyl-based synthetic polymers such as polyvinyl alcohol, polyoxyethylene, polyvinylpyrrolidone, polyvinylpyridine, polyacrylamide, polyvinyl formamide, polyethyleneimine, polyvinyloxazoline, polyvinylimidazole, and polyallylamine; and modified products of natural polysaccharides such as hydroxyethyl cellulose, carboxymethyl cellulose, and processed starch.

The water-soluble polymer may be any of a polymer obtained by polymerizing one kind of monomer or a copolymer obtained by copolymerizing two or more kinds of monomers.

Examples of the monomer include monomers selected from the group consisting of a monomer having a carboxy group, a monomer having a hydroxy group, a monomer having a polyethylene oxide chain, a monomer having an amino group, and a monomer having a heterocyclic ring.

A content of a constitutional unit derived from the monomer selected from the group in the water-soluble polymer is preferably 95% to 100% by mass, and more preferably 99% to 100% by mass with respect to a total mass of the water-soluble polymer.

Examples of the polymer also include the water-soluble polymers described in paragraphs [0043] to [0047] of JP2016-171294A, the content of which is incorporated herein by reference.

A molecular weight (in a case of having a molecular weight distribution, a weight-average molecular weight) of the polymer is preferably 300 or more, more preferably more than 600, still more preferably 2,000 or more, and particularly preferably 10,000 or more. An upper limit thereof is preferably 1,500,000 or less, and more preferably 1,000,000 or less.

In a case where the polymer is a water-soluble polymer, a weight-average molecular weight of the water-soluble polymer is preferably 300 or more, more preferably 2,000 or more, and still more preferably 10,000 or more. An upper limit thereof is preferably 1,500,000 or less, more preferably 1,200,000 or less, and still more preferably 1,000,000 or less.

The polymer preferably has a constitutional unit having a carboxy group (a constitutional unit derived from a (meth)acrylic acid, or the like). A content of the constitutional unit having a carboxy group is preferably 30% to 100% by mass, more preferably 70% to 100% by mass, and still more preferably 85% to 100% by mass with respect to the total mass of the polymer.

The polymer may be used alone or in combination of two or more kinds thereof.

A content of the polymer is preferably 0.000001% to 50% by mass, more preferably 0.00001% to 20% by mass, and still more preferably 0.0001% to 10% by mass with respect to the total mass of components excluding a solvent of the treatment liquid. In a case where the content of the polymer is within the range, the polymer is appropriately adsorbed on a surface of the substrate, contributing to the improvement of the metal corrosion prevention performance of the treatment liquid, and a balance in the viscosity and/or the cleaning performance of the treatment liquid is also excellent.

### [Solvent]

The treatment liquid may include a solvent.

Examples of the solvent include water and an organic solvent, and water is preferable. Examples of the water include distilled water, deionized water, and pure water (ultrapure water). As the water, pure water (ultrapure water) is preferable from the viewpoint that it has a less influence on a semiconductor substrate in a step of manufacturing the semiconductor substrate.

A content of the water is not particularly limited as long as it is a balance of components that can be included in the treatment liquid. Specifically, the content of the water is preferably 1.0% by mass or more, more preferably 30.0% by mass or more, still more preferably 50.0% by mass or more, and particularly preferably 60.0% by mass or more with respect to the total mass of the treatment liquid. An upper limit thereof is preferably 99.99% by mass or less, more preferably 99.9% by mass or less, and still more preferably 99.0% by mass or less with respect to the total mass of the treatment liquid.

Examples of the organic solvent include known organic solvents, and hydrophilic organic solvents such as an alcohol and a ketone are preferable.

Examples of the organic solvent include the organic solvents described in paragraphs to of JP2021-052186A, the content of which is incorporated herein by reference.

### [Other Components]

The treatment liquid may include other components, in addition to the above-mentioned various components.

Examples of such other components include an amine compound, a quaternary ammonium compound, a pH adjuster, a surfactant, and a fluorine compound.

Such other components may be used alone or in combination of two or more kinds thereof.

### <Amine Compound>

The amine compound is a compound different from the above-mentioned various components that can be included in the treatment liquid.

The amine compound is a compound having at least one amino group selected from the group consisting of a primary amino group, a secondary amino group, and a tertiary amino group.

Furthermore, in a case where the amine compound has different classes of amino groups, the amine compound is classified into an amine compound having the highest amino group.

Examples of the amine compound include an aliphatic amine and a guanidine compound other than arginine.

The amine compound may be chain-like (linear or branched) or cyclic.

### (Aliphatic Amine)

Examples of the aliphatic amine include a primary aliphatic amine (aliphatic amine having a primary amino group), a secondary aliphatic amine (aliphatic amine having a secondary amino group), and a tertiary aliphatic amine (aliphatic amine having a tertiary aliphatic amine).

Examples of the primary chain-like aliphatic amine include methylamine, ethylamine, propylamine, dimethylamine, diethylamine, n-butylamine, 3-methoxypropylamine, tert-butylamine, n-hexylamine, n-octylamine, and 2-ethylhexylamine.

Examples of the primary cyclic aliphatic amine include cyclohexylamine.

Examples of the secondary chain-like aliphatic amine include alkylenediamines such as ethylenediamine (EDA), 1,3-propanediamine (PDA), 1,2-propanediamine, 1,3-butanediamine, and 1,4-butanediamine, and polyalkylpolyamines such as diethylenetriamine (DETA), triethylenetetramine (TETA), bis(aminopropyl)ethylenediamine (BAPEDA), and tetraethylenepentamine.

Examples of the secondary cyclic aliphatic amine include piperazine, 2-methylpiperazine, 2,5-dimethylpiperazine, and 2,6-dimethylpiperazine.

Examples of the tertiary aliphatic amine include a tertiary aliphatic amine which has a tertiary amino group in the molecule and does not have an aromatic ring group.

Examples of the tertiary chain-like aliphatic amine include tertiary alkyl amines such as trimethylamine and triethylamine, alkylene amines such as 1,3-bis(dimethylamino)butane, and polyalkylpolyamines such as N,N,N′,N″,N″-pentamethyldiethylenetriamine.

Examples of the tertiary cyclic aliphatic amine include a tertiary aliphatic amine having a nitrogen atom as a ring member atom and having a non-aromatic heterocyclic ring.

Examples of the tertiary cyclic aliphatic amine include a cyclic amidine compound and a piperazine compound.

### (Cyclic Amidine Compound)

The cyclic amidine compound is a compound having a heterocyclic ring including an amidine structure (>N—C═N—) in the ring.

The number of ring members in the heterocyclic ring included in the cyclic amidine compound is preferably 5 or 6, and more preferably 6.

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimid[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimid[1.2-a]azepine, and creatinine, and DBU or DBN is preferable.

### (Piperazine Compound)

The piperazine compound is a compound having a hetero-6-membered ring in which an opposite —CH— group of a cyclohexane ring is replaced with a tertiary amino group (>N—) (a piperazine ring).

Examples of the piperazine compound include 1-methylpiperazine, 1-ethylpiperazine, 1-propylpiperazine, 1-butylpiperazine, 1,4-dimethylpiperazine, 1-phenylpiperazine, N-(2-aminoethyl)piperazine (AEP), 1,4-bis(2-aminoethyl)piperazine (BAEP), 1,4-bis(3-aminopropyl)piperazine (BAPP), and 1,4-diazabicyclo[2.2.2]octane (DABCO), and DABCO is preferable.

Examples of the tertiary cyclic aliphatic amine also include a non-aromatic compound having a hetero-5-membered ring such as 1,3-dimethyl-2-imidazolidinone, and a compound having a 7-membered ring including a nitrogen atom.

### <Quaternary Ammonium Compound>

The quaternary ammonium compound is a compound different from the above-mentioned components included in the treatment liquid.

Examples of the quaternary ammonium compound include quaternary ammonium hydroxide, quaternary ammonium fluoride, quaternary ammonium bromide, quaternary ammonium iodide, quaternary ammonium acetate, and quaternary ammonium carbonate.

Examples of the quaternary ammonium compound include tris(2-hydroxyethyl)methylammonium hydroxide (THEMAH), tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-Hydroxyethyl)dimethylammonium hydroxide, tri(2-hydroxyethyl)methylammonium hydroxide, tetra(2-hydroxyethyl) ammonium hydroxide, benzyltrimethylammonium hydroxide (BTMAH), and cetyltrimethylammonium hydroxide, and THEMAH is preferable.

As the quaternary ammonium compound, for example, the compounds described in paragraph of JP2018-107353A, the content of which is incorporated herein by reference, can also be used.

It is also preferable that the quaternary ammonium compound has an asymmetric structure. The description that the quaternary ammonium compound “has an asymmetric structure” means that none of four substituents (for example, hydrocarbon groups) substituted with nitrogen atoms are the same.

Examples of the quaternary ammonium compound having an asymmetric structure include THEMAH, TMEAH, DEDMAH, TEMAH, choline, and bis(2-hydroxyethyl)dimethylammonium hydroxide.

### <pH Adjuster>

The pH adjuster is a compound different from the above-mentioned components included in the treatment liquid.

Examples of the pH adjuster include a basic compound and an acidic compound.

In addition, a pH of the treatment liquid may be adjusted by adjusting an adding amount of the above-mentioned various components that can be included in the treatment liquid.

Examples of the pH adjuster include paragraphs [0053] and [0054] of WO2019-151141A and paragraph [0021] of WO2019-151001A, the content of which is incorporated herein by reference.

A content of the pH adjuster is appropriately adjusted according to the kinds and the amounts of other components and the pH of the target treatment liquid.

The content of the pH adjuster is preferably 0.2% to 20.0% by mass, more preferably 1.0% to 10.0% by mass, and still more preferably 1.5% to 5.0% by mass with respect to the total mass of the components excluding the solvent in the treatment liquid.

### <Surfactant>

The surfactant is a compound having a hydrophilic group and a hydrophobic group (lipophilic group) in one molecule.

Examples of the surfactant include an anionic surfactant, a cationic surfactant, an amphoteric surfactant, and a nonionic surfactant.

Examples of the surfactant include those described in paragraphs [0091] to [0109] of WO2021/054009A, the content of which is incorporated herein by reference.

A content of the surfactant is preferably 1.0% to 30.0% by mass, more preferably 5.0% to 20.0% by mass, and still more preferably 10.0% to 20.0% by mass with respect to the total mass of the components excluding the solvent in the treatment liquid.

### <Fluorine Compound>

Examples of the fluorine compound include the compounds described in paragraphs to of JP2005-150236A, the content of which is incorporated herein by reference.

The contents of the various components that can be included in the treatment liquid can be measured according to a known method such as gas chromatography-mass spectrometry (GC-MS), liquid chromatography-mass spectrometry (LC-MS), and ion-exchange chromatography (IC).

### [Physical Properties of Treatment Liquid]

<pH>

A pH of the treatment liquid is often 1.0 to 13.0, preferably 4.0 to 8.0, and more preferably 5.0 to 7.0.

A pH of the treatment liquid before dilution is often 1.0 to 13.0, preferably 3.0 to 9.0, and more preferably 4.0 to 8.0.

A pH of the treatment liquid after dilution (for example, 200-fold dilution (volume ratio)) is often 1.0 to 13.0, preferably 3.5 to 9.0, more preferably 4.0 to 8.0, and still more preferably 5.0 to 7.0.

The pH of the treatment liquid can be measured by a method in accordance with JIS Z8802-1984 using a known pH meter. The pH is a value at a measurement temperature of 25° C.

### <Content of Metal Impurities>

A content (measured as an ion concentration) of any of metal impurities (metal elements of Fe, Co, Na, Cu, Mg, Mn, Li, Al, Cr, Ni, Zn, Sn, and Ag) is preferably 5 ppm by mass or less, and more preferably 1 ppm by mass or less with respect to the total mass of the treatment liquid. From the viewpoint of applications to the manufacture of state-of-the-art semiconductor elements, the content of the metal impurities is still more preferably 100 ppb by mass or less, particularly preferably less than 10 ppb by mass, and most preferably a detection limit value or less with respect to the total mass of the treatment liquid. A lower limit thereof is often 0 ppb by mass or more with respect to the total mass of the treatment liquid.

Examples of a method for reducing the metal content include performing a purification treatment such as distillation and filtration using an ion exchange resin or a filter at a stage of raw materials used in the production of the treatment liquid or a stage after the production of the treatment liquid.

Examples of other methods for reducing the metal content include using a container with less elution of impurities, which will be described later, as a container that accommodates the raw material or the produced treatment liquid. In addition, other examples thereof include, in order to suppress the elution of metal components from a pipe or the like during the production of the treatment liquid, lining an inner wall of the pipe with a fluororesin.

### <Inorganic Particles and Organic Particles>

A sum of the contents of inorganic particles and organic particles is preferably 1.0% by mass or less, more preferably 0.1% by mass or less, still more preferably 0.01% by mass or less, and particularly preferably a detection limit value or less with respect to the total mass of the treatment liquid. A lower limit thereof is preferably 0% by mass or more with respect to the total mass of the treatment liquid.

The inorganic particles and the organic particles that can be included in the treatment liquid correspond to, for example, particles such as organic solids and inorganic solids contained as impurities in raw materials, and particles such as organic solids and inorganic solids brought in as contaminants during the preparation of the treatment liquid, in which those particles are finally present as particles without being dissolved in the treatment liquid.

A content of the inorganic particles and the organic particles present in the treatment liquid can be measured in a liquid phase by using a commercially available measuring device in a light scattering type liquid particle measuring method using a laser as a light source.

Examples of a method for removing the inorganic particles and the organic particles include a purification treatment such as filtering, which will be described later.

### [Production of Treatment Liquid]

The treatment liquid can be produced by a known method.

It is preferable that a method for producing the treatment liquid includes a liquid preparation step.

### [Liquid Preparation Step]

The liquid preparation step of the treatment liquid is, for example, a step of preparing the treatment liquid by mixing the above-mentioned various components that can be included in the treatment liquid.

The order or the timing of mixing together the various components is not particularly limited. Examples of the liquid preparation step include a method in which various components are added into a container filled with purified pure water (ultrapure water), and stirred, and a pH adjuster is added thereto as necessary to prepare a liquid. The method for adding the pure water and the various components into the container may be either of batch addition and divided addition.

Examples of the stirring method in the liquid preparation step of the treatment liquid include a method of carrying out stirring using a known stirrer or a known disperser.

Examples of the stirrer include an industrial mixer, a portable stirrer, a mechanical stirrer, and a magnetic stirrer. Examples of the disperser include an industrial disperser, a homogenizer, an ultrasonic disperser, and a beads mill.

A storage temperature of the mixing of the above-mentioned various components in the liquid preparation step of the treatment liquid, a purification treatment described below, and the produced treatment liquid is preferably 40° C. or lower, and more preferably 30° C. or lower. A lower limit thereof is preferably 5° C. or higher, and more preferably 10° C. or higher.

### <Purification Treatment>

It is preferable that at least one of the raw materials of the treatment liquid is subjected to a purification treatment before the liquid preparation step.

A purity of the raw material after the purification treatment is preferably 99% by mass or more, and more preferably 99.9% by mass or more. An upper limit thereof is preferably 99.9999% by mass or less.

Examples of the purification treatment include known methods such as a distillation treatment and a filtering treatment, which will be described below, for example, an ion exchange resin, a reverse osmosis membrane (RO membrane), and filtration.

The purification treatment may be carried out by combining a plurality of the purification methods. For example, raw materials are subjected to a primary purification treatment by passing through an RO membrane, and then the obtained raw materials are subjected to a secondary purification treatment by passing through a purification device consisting of a cation-exchange resin, an anion-exchange resin, or a mixed-bed type ion exchange resin. In addition, the purification treatment may be carried out a plurality of times.

Examples of a filter used for the filtering include known filters for filtration.

From the viewpoint of being able to remove high-polarity contaminants which tend to cause defects, examples of a material of the filter include fluororesins such as polytetrafluoroethylene (PTFE) and tetrafluoroethylene perfluoroalkyl vinyl ether copolymer (PFA), polyamide-based resins such as nylon, and polyolefin resins (including those with a high density and an ultra-high molecular weight) such as polyethylene and polypropylene (PP); and polyethylene, polypropylene (including high-density polypropylene), the fluororesin (including PTFE and PFA), or the polyamide resin (including nylon) is preferable, and the fluororesin is more preferable.

A critical surface tension of the filter is preferably 70 to 95 mN/m and more preferably 75 to 85 mN/m. In a case where the critical surface tension is within the range, it is possible to remove high-polarity contaminants which tend to cause defects. As the critical surface tension of the filter, a nominal value of the manufacturer can be used.

A pore diameter of the filter is preferably 2 to 20 nm, and more preferably 2 to 15 nm. In a case where the pore diameter of the filter is within the range, it is possible to suppress filtration clogging and to remove fine foreign substances such as impurities and aggregates. As the pore diameter of the filter, a nominal value of the manufacturer can be used.

The filtering may be carried out once or twice or more.

In a case where the filtering is carried out twice or more, the filters used for the filtering may be the same or different from each other.

A temperature of the filtering is preferably 25° C. or lower, more preferably 23° C. or lower, and still more preferably 20° C. or lower. A lower limit thereof is preferably 0° C. or higher, more preferably 5° C. or higher, and still more preferably 10° C. or higher. In a case where the filtering is carried out in the range, it is possible to remove foreign substances and impurities dissolved in the raw materials.

### <Container>

The treatment liquid (including the aspect of diluted treatment liquid which will be described later) can be added in any container to be stored and transported as long as the container is not corroded.

As the container, preferred is a container for semiconductor applications that has a high degree of internal cleanliness and that prevents impurities from leaching from the inner wall of the accommodating portion of the container into the treatment liquid.

Examples of the container include a commercially available container for a semiconductor treatment liquid. Specific examples thereof include CLEAN BOTTLE series (manufactured by AICELLO CORPORATION) and PURE BOTTLE (manufactured by KODAMA PLASTICS Co., Ltd.).

In addition, as the container, preferred is a container in which a liquid contact portion with the treatment liquid, such as the inner wall of the accommodating portion of the container, is made of a fluororesin (perfluororesin) or a metal that has been subjected to an antirust treatment and a metal elution prevention treatment.

The inner wall of the container is preferably formed from at least one resin selected from the group consisting of a polyethylene resin, a polypropylene resin, and a polyethylene-polypropylene resin or another resin different from these resins; or a metal which has been subjected to an antirust treatment and a metal elution prevention treatment, such as stainless steel, Hastelloy, Inconel, and Monel.

The different resin is preferably a fluororesin (perfluororesin).

With a container having an inner wall formed of a fluororesin is used, elution of ethylene and propylene oligomers can be further suppressed than in a case of a container having an inner wall formed of a polyethylene resin, a polypropylene resin, or a polyethylene-polypropylene resin.

Examples of the container having an inner wall formed of a fluororesin include a FluoroPure PFA composite drum (manufactured by Entegris, Inc.) and the containers described JP1991-502677A (JP-H03-502677A), WO2004/016526A, and WO99/046309A.

In addition, it is also preferable that the inner wall of the container is made of quartz or a metal material finished up with electropolishing (electropolished metal material), other than the fluororesin.

As a metal material used for producing the electropolished metal material, preferred is a metal material including at least one selected from the group consisting of chromium and nickel, in which a total content of chromium and nickel is more than 25% by mass with respect to a total mass of the metal material. Examples thereof include stainless steel and a nickel-chromium alloy.

The total content of chromium and nickel in the metal material is more preferably 30% by mass or more with respect to the total mass of the metal material. An upper limit thereof is preferably 90% by mass or less with respect to the total mass of the metal material.

Examples of a method for electropolishing the metal material include known methods, and specific examples thereof include the methods described in paragraphs [0011] to [0014] of JP2015-227501A and paragraphs [0036] to [0042] of JP2008-264929A.

It is preferable that the inside of the container is cleaned before the container is filled with the treatment liquid.

Examples of the cleaning method include known methods. With regard to a liquid used for the cleaning, it is preferable that the amount of metal impurities in the liquid is reduced. The treatment liquid may be bottled in a container such as a gallon bottle and a coated bottle after the production, and then may be transported and stored.

From the viewpoint of preventing changes in components in the treatment liquid during storage, the inside of the container is preferably replaced with inert gas (for example, nitrogen and argon) having a purity of 99.99995% by volume or more, and more preferably replaced with the inert gas with a low moisture content.

A temperature for transportation and storage may be controlled to room temperature (25° C.) or −20° C. to 20° C.

### [Dilution Step]

A dilution step of diluting the treatment liquid obtained in the liquid preparation step with a diluent such as water may be carried out.

The diluted treatment liquid obtained in the dilution step is an aspect of the treatment liquid according to the embodiment of the present invention as long as the requirements of the present invention are satisfied.

A dilution ratio of the diluted treatment liquid in the dilution step can be appropriately adjusted according to the type and the content of various components that can be included in the treatment liquid, the semiconductor substrate as an object to be cleaned, and the like.

A dilution ratio of the diluted treatment liquid to the treatment liquid before the dilution is preferably 10 to 10,000 times, more preferably 20 to 3,000 times, and still more preferably 50 to 1,000 times, in terms of a mass ratio or a volume ratio (volume ratio at 23° C.).

A change in pH before and after the dilution (a difference between the pH of the treatment liquid before the dilution and the pH of the diluted treatment liquid) is preferably 2.5 or less, more preferably 1.8 or less, and still more preferably 1.5 or less. A lower limit thereof is preferably 0.1 or more.

The dilution step may be carried out according to the liquid preparation step of the treatment liquid. Examples of a stirring device and a stirring method used in the dilution step include known stirring devices and stirring methods used in the liquid preparation step.

It is preferable that the water used in the dilution step is subjected to a purification treatment before use. In addition, it is also preferable to subject the diluted treatment liquid obtained in the dilution step to the purification treatment.

Examples of the purification treatment include the ion component reducing treatments using an ion exchange resin, an RO membrane, and the like, and the foreign substance removal using filtering, which are described as the purification treatment for the treatment liquid above, and it is preferable to carry out any one of these treatments.

### [Clean Room]

It is preferable that handlings such as production of a treatment liquid, opening and cleaning of a container, and filling of the treatment liquid, treatment analysis, and measurements are all performed in a clean room.

It is preferable that the clean room satisfies 14644-1 clean room standards.

In addition, the clean room preferably meets any of international organization for standardization (ISO) class 1, ISO class 2, ISO class 3, or ISO class 4, more preferably meets ISO class 1 or ISO class 2, and still more preferably meets ISO class 1.

### [Uses of Treatment Liquid]

The treatment liquid is preferably used in a cleaning step of cleaning a semiconductor substrate, and more preferably used in a cleaning step of cleaning a semiconductor substrate having tungsten, which has been subjected to a CMP treatment. In addition, the treatment liquid can also be used for cleaning a semiconductor substrate in a process for manufacturing a semiconductor substrate.

As described above, for the cleaning of the semiconductor substrate, a diluted treatment liquid obtained by diluting the treatment liquid may be used.

### [Object to Be Cleaned]

Examples of an object to be cleaned by the treatment liquid include a semiconductor substrate having a metal film including tungsten (W) on the semiconductor substrate.

In the present specification, the expression, “on the semiconductor substrate”, is used to encompass, for example, front and back surfaces, a side surface, and the inside of a groove of the semiconductor substrate. In addition, the metal film on the semiconductor substrate encompasses not only a case where the metal film is directly on a surface of the semiconductor substrate but also a case where the metal film is present on the semiconductor substrate through another layer.

Examples of the metal included in the metal film include tungsten (W).

The metal film may include a metal other than W. Examples of such other metals include at least one metal M selected from the group consisting of copper (Cu), cobalt (Co), titanium (Ti), tantalum (Ta), ruthenium (Ru), chromium (Cr), hafnium (Hf), osmium (Os), platinum (Pt), nickel (Ni), manganese (Mn), zirconium (Zr), molybdenum (Mo), lanthanum (La), and iridium (Ir).

Examples of the semiconductor substrate, which is the object to be cleaned by the treatment liquid, include a substrate that has a metal wiring line film, a barrier metal, and an insulating film on a surface of a wafer constituting the semiconductor substrate.

Examples of the wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like).

Examples of the silicon of the silicon wafer include amorphous silicon, single crystal silicon, polycrystalline silicon, and polysilicon.

As the wafer, a wafer consisting of a silicon-based material, such as a silicon wafer, a silicon carbide wafer, and a resin-based wafer (a glass epoxy wafer) including silicon, is preferable.

The semiconductor substrate may further have an insulating film on the wafer.

Examples of the insulating film include a silicon oxide film (for example, a silicon dioxide (SiO₂) film, a tetraethyl orthosilicate (Si(OC₂H₅)₄) film (TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film).

Examples of the metal film including tungsten (tungsten-containing film) include a metal film consisting of only tungsten (tungsten metal film) and a metal film made of an alloy consisting of tungsten and a metal other than tungsten (tungsten alloy metal film).

Examples of the tungsten alloy metal film include a tungsten-titanium alloy metal film (a WTi alloy metal film), and a tungsten-cobalt alloy metal film (a WCo alloy metal film).

The tungsten-containing film can be used as, for example, a barrier metal or a connection part between a via and a wiring line.

A method for forming the insulating film and the tungsten-containing film on a wafer constituting the semiconductor substrate is not particularly limited as long as it is a known method.

Examples of the method for forming the insulating film include a method in which a wafer constituting a semiconductor substrate is subjected to a heat treatment in the presence of an oxygen gas to form a silicon oxide film, and then a gas of silane and ammonia is introduced thereto to form a silicon nitride film by a chemical vapor deposition (CVD) method.

Examples of a method for forming the tungsten-containing film include a method in which a circuit is formed on a wafer having the insulating film by a known method with as a resist or the like, and then the tungsten-containing film and a cobalt-containing film are formed by a method such as plating and a CVD method.

### <CMP Treatment>

The CMP treatment is a treatment in which a surface of a substrate having a metal wiring line film, a barrier metal, and an insulating film is flattened by a combined action of a chemical action and a mechanical polishing using a polishing slurry including polishing fine particles (abrasive grains).

A surface of the semiconductor substrate, which has been subjected to the CMP treatment, may have impurities remaining thereon, such as abrasive grains (for example, silica and alumina) used in the CMP treatment, a polished metal wiring line film, and metal impurities (metal residues) derived from the barrier metal. In addition, organic impurities derived from a CMP treatment liquid used in the CMP treatment may remain. For example, since these impurities may cause a short-circuit between wiring lines and deteriorate electrical characteristics of the semiconductor substrate, the semiconductor substrate which has been subjected to a CMP treatment is subjected to a cleaning treatment of removing these impurities from the surface.

Examples of the semiconductor substrate which has been subjected to a CMP treatment include the substrates which have been subjected to a CMP treatment, described in Journal of the Japan Society for Precision Engineering, Vol. 84, No. 3, 2018.

It is preferable to use a polishing liquid during the CMP treatment.

Examples of the polishing liquid include a polishing liquid including iron ions and hydrogen peroxide, or a polishing liquid including chemically modified colloidal silica (for example, cationization modification and anionization modification).

As the polishing liquid, the polishing liquids containing an iron complex described in JP2020-068378A, JP2020-015899A, and U.S. patent Ser. No. 11/043,151, or the chemically modified polishing liquids including colloidal silica described in JP2021-082645A are preferable.

### <Buffing Treatment>

The surface of the semiconductor substrate which is the object to be cleaned by the treatment liquid may be subjected to a buffing treatment after being subjected to the CMP treatment.

The buffing treatment is a treatment of reducing impurities on the surface of the semiconductor substrate using a polishing pad. Specifically, the surface of the semiconductor substrate which has been subjected to the CMP treatment is brought into contact with the polishing pad, and the semiconductor substrate and the polishing pad are relatively slid while supplying a composition for the buffing treatment to a contact portion. As a result, impurities on the surface of the semiconductor substrate are removed by a frictional force of the polishing pad and a chemical action of a composition for a buffing treatment.

As the composition for a buffing treatment, a known composition for a buffing treatment can be appropriately used depending on the type of the semiconductor substrate, and the type and the amount of the impurities to be removed. Examples of components included in the composition for a buffing treatment include a water-soluble polymer such as polyvinyl alcohol, water as a dispersion medium, and an acid such as nitric acid.

In addition, as the buffing treatment, it is preferable that the semiconductor substrate is buffed using the treatment liquid as the composition for the buffing treatment.

A polishing device, polishing conditions, and the like, which are used in the buffing treatment, can be appropriately selected from known devices and conditions according to the type of the semiconductor substrate, the object to be removed, and the like. Examples of the buffing treatment include the treatments described in paragraphs [0085] to [0088] of WO2017/169539A, the content of which is incorporated herein by reference.

### [Cleaning Method]

As the cleaning method using the treatment liquid, a method for cleaning a semiconductor substrate is preferable.

The method for cleaning a semiconductor substrate is not particularly limited as long as it includes a cleaning step of cleaning a semiconductor substrate using the treatment liquid.

The semiconductor substrate is preferably a semiconductor substrate which has been subjected to a CMP treatment.

The method for cleaning a semiconductor substrate also preferably includes a step of applying the diluted treatment liquid obtained in the dilution step to the semiconductor substrate which has been subjected to the CMP treatment to carry out cleaning.

Examples of the cleaning step of cleaning the semiconductor substrate using the treatment liquid include a known method which is performed on a CMP-treated semiconductor substrate.

Specifically, in scrub cleaning in which a cleaning member such as a brush is physically brought into contact with a surface of a semiconductor substrate while supplying a treatment liquid to the semiconductor substrate to remove residues; immersion-type cleaning in which a semiconductor substrate is immersed in a treatment liquid, a spinning (dropping)-type cleaning in which a treatment liquid is added dropwise while rotating a semiconductor substrate; a spraying-type cleaning in which a treatment liquid is sprayed; and the like, it is preferable to subject the treatment liquid in which the semiconductor substrate is immersed to an ultrasonic treatment from the viewpoint that impurities remaining on a surface of the semiconductor substrate can be further reduced.

The cleaning step may be carried out once or twice or more. In a case of performing the cleaning twice or more, the same method may be repeated or different methods may be combined.

The method for cleaning a semiconductor substrate may be a single-wafer method or a batch method.

The single-wafer method is a method of treating semiconductor substrates one by one and the batch method is a method of treating a plurality of semiconductor substrates at the same time.

A temperature of the treatment liquid used for cleaning a semiconductor substrate is not particularly limited.

Examples of the temperature of the treatment liquid include room temperature (25° C.), and from the viewpoint of improving cleaning performance and suppressing a damage to members, the temperature is preferably 10° C. to 60° C., and more preferably 15° C. to 50° C.

The pH of the treatment liquid and the pH of the diluted treatment liquid are each preferably those in the above-mentioned suitable aspects of pH.

A cleaning time in the cleaning of the semiconductor substrate can be appropriately changed depending on the type, content, and the like of the components included in the treatment liquid. The cleaning time is preferably 10 to 120 seconds, more preferably 20 to 90 seconds, and still more preferably 30 to 60 seconds.

A supply amount (supply rate) of the treatment liquid in the cleaning step for the semiconductor substrate is preferably 50 to 5,000 mL/min, and more preferably 500 to 2,000 mL/min.

In the cleaning of the semiconductor substrate, a mechanical stirring method may be used in order to further improve the cleaning performance of the treatment liquid.

Examples of the mechanical stirring method include a method of circulating the treatment liquid on the semiconductor substrate, a method of flowing or spraying the treatment liquid on the semiconductor substrate, and a method of stirring the treatment liquid with ultrasonic waves or megasonic waves.

After the cleaning of the semiconductor substrate, a rinsing step of rinsing and washing the semiconductor substrate with a solvent may be performed.

The rinsing step is preferably a step which is performed subsequently after the cleaning step for the semiconductor substrate and involves rinsing performed with a rinsing liquid over 5 to 300 seconds. The rinsing step may be carried out using the mechanical stirring method.

Examples of the rinsing liquid include water (preferably deionized water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (for example, aqueous ammonium hydroxide which has been diluted) may be used.

Examples of the method of bringing a rinsing solvent into contact with the semiconductor substrate include a method of bringing the treatment liquid into contact with the semiconductor substrate.

After the rinsing step, a drying step of drying the semiconductor substrate may be carried out.

Examples of the drying method include a spin drying method, a method of flowing a dry gas onto a semiconductor substrate, a method of heating a substrate by a heating unit such as a hot plate and an infrared lamp, a Marangoni drying method, a Rotagoni drying method, an isopropyl alcohol (IPA) drying method, and a method of a combination of these methods.

### [Method for Manufacturing Semiconductor Element]

In a known method for manufacturing a semiconductor element, it is also preferable to use the above-mentioned cleaning method.

### EXAMPLES

Hereinbelow, the present invention will be described in more detail with reference to Examples. The materials, the amounts of the materials to be used, the proportions, and the like shown in the Examples below may be modified as appropriate as long as the modifications do not depart from the spirit of the present invention, and the scope of the present invention is not limited to Examples shown below.

In Examples and Comparative Examples, the pH of a treatment liquid was measured at 25° C. using a pH meter (F-74 manufactured by HORIBA, Ltd.) in accordance with JIS Z8802-1984. In addition, the pKa of an acid group and the pKa of a basic group, each contained in a specific compound, are values in water (temperature: 25° C.), calculated using Calculator Plugins (manufactured by Fujitsu Co., Ltd.), and the pKa of the basic group is a value of a conjugate acid of the basic group.

In the production of treatment liquids of Examples and Comparative Examples, all of handling of a container, and production, filling, storage, and analytical measurement of the treatment liquids were performed in a clean room satisfying a level of ISO Class 2 or lower.

### [Various Components of Treatment Liquid]

The following various components were used to produce a treatment liquid.

As various components used in Examples, those all classified into a semiconductor grade or a high-purity grade equivalent thereto were used.

### [Specific Compound]

Hereinafter, the chemical structure of the specific compound, the pKa of each acid group, and the pKa of each basic group will be shown.

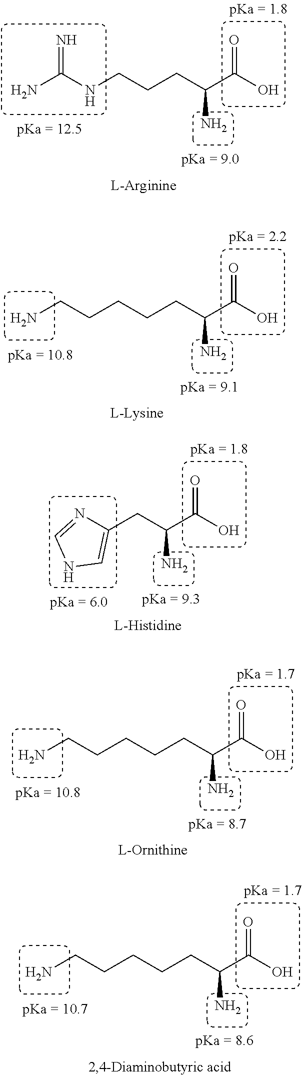 [SMILES: N=C(N)NCCC[C@H](N)C(=O)O ; NCCCCC[C@H](N)C(=O)O ; N[C@@H](Cc1c[nH]cn1)C(=O)O ; NCCCCC[C@H](N)C(=O)O ; NCCCCC[C@H](N)C(=O)O]

### [Amino Alcohol]

Tris: Tris(hydroxymethyl)aminomethane
MEA: Monoethanolamine
Bis-Tris: Bis(2-hydroxyethyl)aminotris(hydroxymethyl)methane
Bis-Tris-Propane: 1,3-Bis[tris(hydroxymethyl)methylamino]propane
2-Amino-1,3-propanediol
3-Amino-1,2-propanediol
1,3-Diamino-2-propanol
MDEA: N-Methyldiethanolamine

### [Antimicrobial Agent]

Sorbic acid
Methylchloroisothiazolinone
Methylisothiazolinone
Benzalkonium chloride
Benzethonium chloride
Domiphen bromide
Salicylic acid
Benzoic acid
Phenoxyethanol
1,2-Pentanediol
1,2-Hexanediol
Cresol
Chlorothymol
Dichloroxylenol
Hexachlorophene

### [Organic Acid]

Citric acid
Glycolic acid
Malic acid
Tartaric acid
Gluconic acid
Oxalic acid
Trimellitic acid

### [Additive]

Nonionic X: Compound shown below

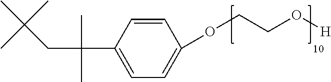

THEMAH: Tris(2-hydroxyethyl)methylammonium hydroxide
ARON A-10SL: Polyacrylic acid (Mw: 6,000), manufactured by Toagosei Co., Ltd.
NONPOL PWA-50W: Polymaleic acid (Mw: 2,000), manufactured by NOF Corporation
Ethylenediamine

### [Water]

Ultrapure water

### [pH Adjuster]

As a pH adjuster, potassium hydroxide and/or sulfuric acid was used as necessary.

### [Production of Treatment Liquid]

A treatment liquid of Example 1 was produced according to the following procedure.

L-arginine, tris(hydroxymethyl)aminomethane, sorbic acid, citric acid, and a pH adjuster were added to ultrapure water in the amounts such that a treatment liquid finally obtained was shown in the table below, and the mixture was sufficiently stirred to obtain a treatment liquid of Example 1. Treatment liquids other than Example 1 were each produced in accordance with the production method of Example 1.

In any of the treatment liquids, a content of the pH adjuster with respect to a total mass of the treatment liquid was 2% by mass or less.

### [Diluted Treatment Liquid]

1 mL of each of the obtained treatment liquids was collected by separation and diluted 200-fold by volume with ultrapure water to prepare each diluted treatment liquid (200 mL). [Storage Stability]

Storage stability was evaluated using each treatment liquid (the treatment liquid before dilution).

A simple antibacterial and antifungal test kit (Easicult TTC) manufactured by Orion Corporation, Finland was immersed in each treatment liquid and treated according to the method specified by the kit, and the obtained culture medium was stored at 30ºC for 48 hours. The states before and after the treatment were compared, and the antimicrobial properties were evaluated according to the following evaluation standard.
A: There was no change in the culture medium state before and after the treatment
B: The formation of colonies was slightly confirmed
C: The formation of colonies at 5 to 10 CFU/ml, which is shown in the kit test, could be confirmed
D: The formation of colonies at more than 10 CFU/ml and 103 CFU/ml or less, which is shown in the kit test, could be confirmed
E: The formation of colonies at more than 103 CFU/ml and 104 CFU/ml or less, which is shown in the kit test, was confirmed

### [Cleanability]

Using each treatment liquid (the treatment liquid before dilution), the cleanability (residue removal performance) in a case where a metal film after the CMP treatment had been cleaned was evaluated.

A wafer (diameter: 12 inches) having a metal film consisting of tungsten on a surface thereof was subjected to a CMP treatment, using FREX300SIII (a polishing device, manufactured by Ebara Corporation) and using a polishing liquid which will be described later, under the conditions of a supply rate of the polishing liquid of 200 mL/min, a polishing pressure of 1.5 psi, and a polishing time of 60 seconds.

Then, the temperature of each treatment liquid was adjusted to room temperature) (23° C., and scrub-cleaning was performed for 60 seconds using each treatment liquid, followed by a drying treatment. The number of defects on the polished surface of the obtained wafer was detected using a defect detection device, each defect was observed with a scanning electron microscope (SEM) to perform defect classification. The constituent elements were analyzed by an energy-dispersive X-ray spectroscopy device (EDAX), as necessary, to specify the components. In this manner, the number of defects based on the residues was determined, and the cleanability was evaluated according to the following evaluation standard (Evaluation A indicates the most excellent cleaning performance).

In addition, the cleanability was evaluated according to the same procedure as described above, except that each treatment liquid was changed to each diluted treatment liquid.

Hereinafter, various components of the polishing liquids used in Examples and Comparative Examples will be shown.

Furthermore, the contents of the various component are each a value with respect to a total mass of each polishing liquid.

### <Polishing Liquid 1>: Examples 1 to 75, Comparative Examples 1 to 3, and Examples 80 and 81

Malonic acid: 0.30% by mass
Iron nitrate: 0.02% by mass
Hydrogen peroxide: 2.5% by mass
PL-5 (unmodified colloidal silica, manufactured by Fuso Chemical Co., Ltd.): 1.5% by mass
Water: Balance

### <Polishing Liquid 2>: Examples 76 and 77

Malonic acid: 0.30% by mass
Iron nitrate: 0.02% by mass
Hydrogen peroxide: 2.5% by mass
PL-5D (anion-modified colloidal silica, manufactured by Fuso Chemical Co., Ltd.):

1.5% by mass
Water: Balance

### <Polishing Liquid 3>: Examples 78 and 79

Malonic acid: 0.30% by mass
Iron nitrate: 0.02% by mass
Hydrogen peroxide: 2.5% by mass
PL-5C (cationically modified colloidal silica, manufactured by Fuso Chemical Co., Ltd.): 1.5% by mass
Water: Balance
A: The number of defects is less than 20
B: The number of defects was 20 or more and less than 50
C: The number of defects was 50 or more and less than 100
D: The number of defects was 100 or more and less than 200
E: The number of defects is 200 or more

### [Tungsten (W) Anticorrosion Properties]

W anticorrosion properties were evaluated using each treatment liquid (the treatment liquid before dilution).

A wafer (diameter: 12 inches) on a surface having W thereof was cut to prepare a 2 cm-square wafer coupon. The thickness of the W metal film was 100 nm. The wafer coupon was immersed in each treatment liquid and each metal film was stirred at 250 rpm at room temperature for 30 minutes. The film thickness of the W metal film that disappeared after 30 minutes was measured, and a W corrosion rate per unit time was calculated. The W anticorrosion properties of the treatment liquid were evaluated according to the following evaluation standard.

In addition, the W anticorrosion properties were evaluated according to the same procedure as described above, except that each treatment liquid was changed to each diluted treatment liquid.
A: The W corrosion rate is 0.3 Å/min or less
B: The W corrosion rate is more than 0.3 Å/min and less than 0.5 Å/min
C: The W corrosion rate is 0.5 Å/min or more and less than 1.0 Å/min
D: The W corrosion rate is 1.0 Å/min or more and less than 1.5 Å/min
E: The W corrosion rate is 1.5 Å/min or more

### [Results]

In the tables, the column of “Content (% by mass)” shows the contents (% by mass) of various components with respect to the total mass of the treatment liquid (the treatment liquid before dilution).

“*1” in the column of “pH” means that the pH adjuster was added as necessary in such an amount that the pH of the finally obtained treatment liquid was a numerical value in the column of “pH before dilution”.

The “Balance” of “Water” means the remaining components which are not the components specified as the components of the treatment liquid in the tables.

The column of “A/B” shows the mass ratio of the content of the specific compound to the content of the amino alcohol (the content of the specific compound/the content of the amino alcohol).

The column of “A/C shows the mass ratio of the content of the specific compound to the content of the antimicrobial agent (the content of the specific compound/the content of the antimicrobial agent).

The column of “B/C” shows the mass ratio of the content of the amino alcohol to the content of the antimicrobial agent (the content of the amino alcohol/the content of the antimicrobial agent).

The column of “pH before dilution” shows the pH of the treatment liquid before dilution.

The column of “pH after dilution” shows the pH of the diluted treatment liquid (the treatment liquid that has been diluted 200 times).

Any of the pH's indicate a pH of the treatment liquid or the diluted treatment liquid at 25° C. measured by a pH meter.

TABLE 1

| | Treatment liquid | | | | | | | |
|---|---|---|---|---|---|---|---|---|
| | (A) Specific compound | | (B)Amino alcohol | | (C)Antimicrobial agent | | (D) Organic acid | |
| | | Content | | Content | | Content | | Content |
| Table 1 | Type | (% by mass) | Type | (% by mass) | Type | (% by mass) | Type | (% by mass) |
| Example 1 | L-Arginine | 1.0 | Tris | 3.0 | Sorbic acid | 0.05 | Citric acid | 3.0 |
| Example 2 | L-Arginine | 1.0 | Tris | 3.0 | Sorbic acid | 0.05 | Citric acid | 3.0 |
| Example 3 | L-Arginine | 1.0 | Tris | 3.0 | Sorbic acid | 0.05 | Citric acid | 3.0 |
| Example 4 | L-Arginine | 1.0 | Tris | 3.0 | Sorbic acid | 0.05 | Citric acid | 3.0 |
| Example 5 | L-Arginine | 1.0 | Tris | 3.0 | Sorbic acid | 0.05 | Citric acid | 3.0 |
| Example 6 | L-Arginine | 1.0 | Tris | 3.0 | Sorbic acid | 0.05 | Citric acid | 3.0 |
| Example 7 | L-Arginine | 1.0 | Tris | 3.0 | Sorbic acid | 0.05 | Citric acid | 3.0 |
| Example 8 | L-Arginine | 1.0 | Tris | 3.0 | Sorbic acid | 0.05 | Citric acid | 3.0 |
| Example 9 | L-Arginine | 1.0 | Tris | 3.0 | Sorbic acid | 0.05 | Citric acid | 3.0 |
| Example 10 | L-Arginine | 0.005 | Tris | 0.5 | Sorbic acid | 0.05 | Citric acid | 3.0 |
| Example 11 | L-Arginine | 0.01 | Tris | 0.5 | Sorbic acid | 0.05 | Citric acid | 3.0 |
| Example 12 | L-Arginine | 0.05 | Tris | 0.5 | Sorbic acid | 0.05 | Citric acid | 3.0 |
| Example 13 | L-Arginine | 0.3 | Tris | 0.5 | Sorbic acid | 0.05 | Citric acid | 3.0 |
| Example 14 | L-Arginine | 2.0 | Tris | 0.5 | Sorbic acid | 0.05 | Citric acid | 3.0 |
| Example 15 | L-Arginine | 3.0 | Tris | 0.5 | Sorbic acid | 0.05 | Citric acid | 3.0 |
| Example 16 | L-Arginine | 5.0 | Tris | 0.5 | Sorbic acid | 0.05 | Citric acid | 3.0 |
| Example 17 | L-Lysine | 1.0 | Tris | 3.0 | Sorbic acid | 0.05 | Citric acid | 3.0 |
| Example 18 | L-Histidine | 1.0 | Tris | 3.0 | Sorbic acid | 0.05 | Citric acid | 3.0 |
| Example 19 | L-Ornithine | 1.0 | Tris | 3.0 | Sorbic acid | 0.05 | Citric acid | 3.0 |
| Example 20 | 2,4-Diamino- | 1.0 | Tris | 3.0 | Sorbic acid | 0.05 | Citric acid | 3.0 |
| | butyric acid | | | | | | | |
| Example 21 | L-Arginine | 1.0 | Tris | 3.0 | Sorbic acid | 0.05 | Citric acid | 0.5 |
| Example 22 | L-Arginine | 1.0 | Tris | 3.0 | Sorbic acid | 0.05 | Citric acid | 1.0 |
| Example 23 | L-Arginine | 1.0 | Tris | 3.0 | Sorbic acid | 0.05 | Citric acid | 5.0 |
| Example 24 | L-Arginine | 1.0 | Tris | 3.0 | Sorbic acid | 0.05 | Glycolic acid | 3.0 |
| Example 25 | L-Arginine | 1.0 | Tris | 3.0 | Sorbic acid | 0.05 | Malic acid | 3.0 |
| Example 26 | L-Arginine | 1.0 | Tris | 3.0 | Sorbic acid | 0.05 | Tartaric acid | 3.0 |
| Example 27 | L-Arginine | 1.0 | Tris | 3.0 | Sorbic acid | 0.05 | Gluconic acid | 3.0 |
| Example 28 | L-Arginine | 1.0 | Tris | 3.0 | Sorbic acid | 0.05 | Oxalic acid | 3.0 |
| Example 29 | L-Arginine | 1.0 | Tris | 0.05 | Sorbic acid | 0.05 | Citric acid | 3.0 |
| Example 30 | L-Arginine | 1.0 | Tris | 0.1 | Sorbic acid | 0.05 | Citric acid | 3.0 |
| Example 31 | L-Arginine | 1.0 | Tris | 0.3 | Sorbic acid | 0.05 | Citric acid | 3.0 |
| Example 32 | L-Arginine | 1.0 | Tris | 0.5 | Sorbic acid | 0.05 | Citric acid | 3.0 |
| Example 33 | L-Arginine | 1.0 | Tris | 5.0 | Sorbic acid | 0.05 | Citric acid | 3.0 |
| Example 34 | L-Arginine | 1.0 | Tris | 8.0 | Sorbic acid | 0.05 | Citric acid | 3.0 |
| Example 35 | L-Arginine | 1.0 | Tris | 10.0 | Sorbic acid | 0.05 | Citric acid | 3.0 |
| Example 36 | L-Arginine | 1.0 | Tris | 12.0 | Sorbic acid | 0.05 | Citric acid | 3.0 |
| Example 37 | L-Arginine | 1.0 | MEA | 3.0 | Sorbic acid | 0.05 | Citric acid | 3.0 |
| Example 38 | L-Arginine | 1.0 | Bis-Tris | 3.0 | Sorbic acid | 0.05 | Citric acid | 3.0 |
| Example 39 | L-Arginine | 1.0 | Bis-Tris-Propane | 3.0 | Sorbic acid | 0.05 | Citric acid | 3.0 |
| Example 40 | L-Arginine | 1.0 | 2-Amino-1,3- | 3.0 | Sorbic acid | 0.05 | Citric acid | 3.0 |
| | | | propanediol | | | | | |
| Example 41 | L-Arginine | 1.0 | 3-Amino-1,2- | 3.0 | Sorbic acid | 0.05 | Citric acid | 3.0 |
| | | | propanediol | | | | | |
| Example 42 | L-Arginine | 1.0 | 1,3-Diamino-2- | 3.0 | Sorbic acid | 0.05 | Citric acid | 3.0 |
| | | | propanol | | | | | |
| Example 43 | L-Arginine | 1.0 | Tris | 3.0 | Sorbic acid | 0.001 | Citric acid | 3.0 |
| Example 44 | L-Arginine | 1.0 | Tris | 3.0 | Sorbic acid | 0.005 | Citric acid | 3.0 |
| Example 45 | L-Arginine | 1.0 | Tris | 3.0 | Sorbic acid | 0.01 | Citric acid | 3.0 |
| Example 46 | L-Arginine | 1.0 | Tris | 3.0 | Sorbic acid | 0.02 | Citric acid | 3.0 |
| Example 47 | L-Arginine | 1.0 | Tris | 3.0 | Sorbic acid | 0.3 | Citric acid | 3.0 |
| Example 48 | L-Arginine | 1.0 | Tris | 3.0 | Sorbic acid | 0.5 | Citric acid | 3.0 |
| Example 49 | L-Arginine | 1.0 | Tris | 3.0 | Sorbic acid | 1.0 | Citric acid | 3.0 |
| Example 50 | L-Arginine | 1.0 | Tris | 3.0 | Sorbic acid | 1.5 | Citric acid | 3.0 |
| Example 51 | L-Arginine | 1.0 | Tris | 3.0 | Methyl | 0.05 | Citric acid | 3.0 |
| | | | | | chloroiso- | | | |
| | | | | | thiazolinone | | | |
| Example 52 | L-Arginine | 1.0 | Tris | 3.0 | Methylisothiazolinone | 0.05 | Citric acid | 3.0 |
| Example 53 | L-Arginine | 1.0 | Tris | 3.0 | Benzalkonium chloride | 0.05 | Citric acid | 3.0 |
| Example 54 | L-Arginine | 1.0 | Tris | 3.0 | Benzethonium chloride | 0.05 | Citric acid | 3.0 |
| Example 55 | L-Arginine | 1.0 | Tris | 3.0 | Domiphen bromide | 0.05 | Citric acid | 3.0 |
| Example 56 | L-Arginine | 1.0 | Tris | 3.0 | Salicylic acid | 0.05 | Citric acid | 3.0 |
| Example 57 | L-Arginine | 1.0 | Tris | 3.0 | Benzoic acid | 0.05 | Citric acid | 3.0 |
| Example 58 | L-Arginine | 1.0 | Tris | 3.0 | Phenoxyethanol | 0.05 | Citric acid | 3.0 |
| Example 59 | L-Arginine | 1.0 | Tris | 3.0 | 1,2-Pentanediol | 0.05 | Citric acid | 3.0 |
| Example 60 | L-Arginine | 1.0 | Tris | 3.0 | 1,2-Hexanediol | 0.05 | Citric acid | 3.0 |
| Example 61 | L-Arginine | 1.0 | Tris | 3.0 | Cresol | 0.05 | Citric acid | 3.0 |
| Example 62 | L-Arginine | 1.0 | Tris | 3.0 | Chlorothymol | 0.05 | Citric acid | 3.0 |
| Example 63 | L-Arginine | 1.0 | Tris | 3.0 | Dichloroxylenol | 0.05 | Citric acid | 3.0 |
| Example 64 | L-Arginine | 1.0 | Tris | 3.0 | Hexachlorophene | 0.05 | Citric acid | 3.0 |

TABLE 2

| | | | | | | | | Results | | | | |
|---|---|---|---|---|---|---|---|---|---|---|---|---|
| Table 2 | Treatment liquid | | | | | | | Before dilution | | | After dilution | |
| Continuance | | | | | | pH | pH | | | W | | W |
| of | pH | | | | | before | after | Storage | Clean- | anticorrosion | Clean- | anticorrosion |
| Table 1 | adjuster | Water | A/B | A/C | B/C | dilution | dilution | stability | ability | properties | ability | properties |
| Example 1 | *1 | Balance | 0.33 | 20.00 | 60.00 | 2.0 | 3.2 | A | D | A | D | A |
| Example 2 | *1 | Balance | 0.33 | 20.00 | 60.00 | 3.0 | 3.8 | A | C | A | C | A |
| Example 3 | *1 | Balance | 0.33 | 20.00 | 60.00 | 4.0 | 4.5 | A | B | A | B | B |
| Example 4 | *1 | Balance | 0.33 | 20.00 | 60.00 | 5.0 | 5.5 | A | A | A | B | B |
| Example 5 | *1 | Balance | 0.33 | 20.00 | 60.00 | 6.0 | 6.3 | A | A | A | B | B |
| Example 6 | *1 | Balance | 0.33 | 20.00 | 60.00 | 7.0 | 6.8 | A | A | A | B | B |
| Example 7 | *1 | Balance | 0.33 | 20.00 | 60.00 | 8.0 | 7.6 | A | A | B | A | B |
| Example 8 | *1 | Balance | 0.33 | 20.00 | 60.00 | 9.0 | 8.5 | A | A | C | A | C |
| Example 9 | *1 | Balance | 0.33 | 20.00 | 60.00 | 10.0 | 9.2 | A | A | D | A | D |
| Example 10 | *1 | Balance | 0.01 | 0.10 | 10.00 | 6.0 | 6.3 | A | A | D | A | D |
| Example 11 | *1 | Balance | 0.02 | 0.20 | 10.00 | 6.0 | 6.4 | A | A | C | A | D |
| Example 12 | *1 | Balance | 0.10 | 1.00 | 10.00 | 6.0 | 6.3 | A | A | B | A | C |
| Example 13 | *1 | Balance | 0.60 | 6.00 | 10.00 | 6.0 | 6.2 | A | A | A | B | B |
| Example 14 | *1 | Balance | 4.00 | 40.00 | 10.00 | 6.0 | 6.3 | A | B | A | A | A |
| Example 15 | *1 | Balance | 6.00 | 60.00 | 10.00 | 6.0 | 6.4 | A | C | A | B | A |
| Example 16 | *1 | Balance | 10.00 | 100.00 | 10.00 | 6.0 | 6.5 | A | D | A | C | A |
| Example 17 | *1 | Balance | 0.33 | 20.00 | 60.00 | 6.0 | 6.6 | A | A | A | B | B |
| Example 18 | *1 | Balance | 0.33 | 20.00 | 60.00 | 6.0 | 6.6 | A | A | A | B | B |
| Example 19 | *1 | Balance | 0.33 | 20.00 | 60.00 | 6.0 | 6.5 | A | A | B | B | C |
| Example 20 | *1 | Balance | 0.33 | 20.00 | 60.00 | 6.0 | 6.4 | A | A | B | B | C |
| Example 21 | *1 | Balance | 0.33 | 20.00 | 60.00 | 6.0 | 6.3 | A | B | A | C | B |
| Example 22 | *1 | Balance | 0.33 | 20.00 | 60.00 | 6.0 | 6.4 | A | A | A | B | B |
| Example 23 | *1 | Balance | 0.33 | 20.00 | 60.00 | 6.0 | 6.5 | A | A | B | B | C |
| Example 24 | *1 | Balance | 0.33 | 20.00 | 60.00 | 6.0 | 6.6 | A | C | A | D | B |
| Example 25 | *1 | Balance | 0.33 | 20.00 | 60.00 | 6.0 | 6.5 | A | B | A | C | B |
| Example 26 | *1 | Balance | 0.33 | 20.00 | 60.00 | 6.0 | 6.6 | A | B | A | C | B |
| Example 27 | *1 | Balance | 0.33 | 20.00 | 60.00 | 6.0 | 6.7 | A | C | A | D | B |
| Example 28 | *1 | Balance | 0.33 | 20.00 | 60.00 | 6.0 | 6.5 | A | B | A | C | B |
| Example 29 | *1 | Balance | 20.00 | 20.00 | 1.00 | 6.0 | 6.3 | A | A | C | B | D |
| Example 30 | *1 | Balance | 10.00 | 20.00 | 2.00 | 6.0 | 6.4 | A | A | B | B | C |
| Example 31 | *1 | Balance | 3.33 | 20.00 | 6.00 | 6.0 | 6.3 | A | A | B | B | B |
| Example 32 | *1 | Balance | 2.00 | 20.00 | 10.00 | 6.0 | 6.5 | A | A | A | B | B |
| Example 33 | *1 | Balance | 0.20 | 20.00 | 100.00 | 6.0 | 6.4 | A | A | A | B | B |
| Example 34 | *1 | Balance | 0.13 | 20.00 | 160.00 | 6.0 | 6.3 | A | B | A | B | B |
| Example 35 | *1 | Balance | 0.10 | 20.00 | 200.00 | 6.0 | 6.4 | A | B | A | C | B |
| Example 36 | *1 | Balance | 0.08 | 20.00 | 240.00 | 6.0 | 6.5 | A | C | A | D | B |
| Example 37 | *1 | Balance | 0.33 | 20.00 | 60.00 | 6.0 | 6.6 | A | A | C | B | B |
| Example 38 | *1 | Balance | 0.33 | 20.00 | 60.00 | 6.0 | 6.6 | A | A | A | B | B |
| Example 39 | *1 | Balance | 0.33 | 20.00 | 60.00 | 6.0 | 6.5 | A | A | A | B | B |
| Example 40 | *1 | Balance | 0.33 | 20.00 | 60.00 | 6.0 | 6.6 | A | A | B | B | B |
| Example 41 | *1 | Balance | 0.33 | 20.00 | 60.00 | 6.0 | 6.7 | A | A | B | B | B |
| Example 42 | *1 | Balance | 0.33 | 20.00 | 60.00 | 6.0 | 6.7 | A | A | C | B | B |
| Example 43 | *1 | Balance | 0.33 | 1,000.00 | 3,000.00 | 6.0 | 6.3 | D | A | A | B | B |
| Example 44 | *1 | Balance | 0.33 | 200.00 | 600.00 | 6.0 | 6.3 | C | A | A | B | B |
| Example 45 | *1 | Balance | 0.33 | 100.00 | 300.00 | 6.0 | 6.3 | B | A | A | B | B |
| Example 46 | *1 | Balance | 0.33 | 50.00 | 150.00 | 6.0 | 6.3 | A | A | A | B | B |
| Example 47 | *1 | Balance | 0.33 | 3.33 | 10.00 | 6.0 | 6.3 | A | A | A | B | B |
| Example 48 | *1 | Balance | 0.33 | 2.00 | 6.00 | 6.0 | 6.3 | A | B | A | B | B |
| Example 49 | *1 | Balance | 0.33 | 1.00 | 3.00 | 6.0 | 6.3 | A | C | A | B | B |
| Example 50 | *1 | Balance | 0.33 | 0.67 | 2.00 | 6.0 | 6.4 | A | D | A | C | B |
| Example 51 | *1 | Balance | 0.33 | 20.00 | 60.00 | 6.0 | 6.3 | A | A | A | B | B |
| Example 52 | *1 | Balance | 0.33 | 20.00 | 60.00 | 6.0 | 6.4 | A | A | A | B | B |
| Example 53 | *1 | Balance | 0.33 | 20.00 | 60.00 | 6.0 | 6.3 | B | A | A | B | B |
| Example 54 | *1 | Balance | 0.33 | 20.00 | 60.00 | 6.0 | 6.3 | A | A | A | B | B |
| Example 55 | *1 | Balance | 0.33 | 20.00 | 60.00 | 6.0 | 6.4 | B | A | A | B | B |
| Example 56 | *1 | Balance | 0.33 | 20.00 | 60.00 | 6.0 | 6.3 | A | A | A | B | B |
| Example 57 | *1 | Balance | 0.33 | 20.00 | 60.00 | 6.0 | 6.3 | A | A | A | B | B |
| Example 58 | *1 | Balance | 0.33 | 20.00 | 60.00 | 6.0 | 6.3 | B | A | A | B | B |
| Example 59 | *1 | Balance | 0.33 | 20.00 | 60.00 | 6.0 | 6.3 | B | A | A | B | B |
| Example 60 | *1 | Balance | 0.33 | 20.00 | 60.00 | 6.0 | 6.3 | B | A | A | B | B |
| Example 61 | *1 | Balance | 0.33 | 20.00 | 60.00 | 6.0 | 6.3 | B | A | A | B | B |
| Example 62 | *1 | Balance | 0.33 | 20.00 | 60.00 | 6.0 | 6.4 | B | A | A | B | B |
| Example 63 | *1 | Balance | 0.33 | 20.00 | 60.00 | 6.0 | 6.4 | B | A | A | B | B |
| Example 64 | *1 | Balance | 0.33 | 20.00 | 60.00 | 6.0 | 6.5 | B | A | A | B | B |

TABLE 3

| | Treatment liquid | | | | | | | | | |
|---|---|---|---|---|---|---|---|---|---|---|
| | (A) Specific | | | | | | | | | |
| | compound | | (B) Amino alcohol | | (C) Antimicrobial agent | | (D) Organic acid | | (E) Additive | |
| | | Content | | Content | | Content | | Content | | Content |
| | | (% by | | (% by | | (% by | | (% by | | (% by |
| Table 3 | Type | mass) | Type | mass) | Type | mass) | Type | mass) | Type | mass) |
| Example 65 | L-Arginine | 2.0 | Tris | 3.0 | Sorbic acid | 0.05 | Citric acid | 3.0 | — | — |
| | L-Lysine | | | | | | | | | |
| | (1:1) | | | | | | | | | |
| Example 66 | L-Arginine | 2.0 | Tris | 3.0 | Sorbic acid | 0.05 | Citric acid | 3.0 | — | — |
| | L-Histidine | | | | | | | | | |
| | (1:1) | | | | | | | | | |
| Example 67 | L-Arginine | 1.0 | Tris | 3.0 | Sorbic acid | 0.01 | Citric acid | 3.0 | — | — |
| | | | | | Methylisothiazolinone | | | | | |
| | | | | | (1:1) | | | | | |
| Example 68 | L-Arginine | 1.0 | Tris | 3.0 | Methyl- | 0.01 | Citric acid | 3.0 | — | — |
| | | | | | chloroisothiazolinone | | | | | |
| | | | | | Methylisothiazolinone | | | | | |
| | | | | | (1:1) | | | | | |
| Example 69 | L-Arginine | 1.0 | Tris | 5.0 | Sorbic acid | 0.05 | Citric acid | 3.0 | — | — |
| | | | Bis-Tris | | | | | | | |
| | | | (1:1) | | | | | | | |
| Example 70 | L-Arginine | 1.0 | Tris | 5.0 | Sorbic acid | 0.05 | Citric acid | 3.0 | — | — |
| | | | Bis- | | | | | | | |
| | | | Tris-Propane | | | | | | | |
| | | | (1:1) | | | | | | | |
| Example 71 | L-Arginine | 1.0 | Tris | 3.0 | Sorbic acid | 0.05 | Citric acid | 3.0 | Nonionic X | 0.05 |
| Example 72 | L-Arginine | 1.0 | MDEA | 1.0 | Sorbic acid | 0.05 | Tartaric acid | 3.0 | THEMAH | 3.0 |
| Example 73 | L-Arginine | 1.0 | Tris | 3.0 | Sorbic acid | 0.05 | Citric acid | 3.0 | Aron A-10SL | 0.1 |
| Example 74 | L-Arginine | 1.0 | Tris | 3.0 | Sorbic acid | 0.05 | Citric acid | 3.0 | NOPOL PWA- | 0.1 |
| | | | | | | | | | 50W | |
| Example 75 | L-Arginine | 1.0 | Tris | 3.0 | Sorbic acid | 0.05 | Citric acid | 0.6 | — | — |
| | | | | | | | Trimellitic | | | |
| | | | | | | | acid | | | |
| | | | | | | | (5:1) | | | |
| Example 76 | L-Arginine | 1.0 | Tris | 3.0 | Sorbic acid | 0.05 | Citric acid | 3.0 | — | — |
| Example 77 | L-Arginine | 1.0 | Tris | 3.0 | Sorbic acid | 0.05 | Citric acid | 3.1 | — | — |
| | | | | | | | Trimellitic | | | |
| | | | | | | | acid | | | |
| | | | | | | | (30:1) | | | |
| Example 78 | L-Arginine | 1.0 | Tris | 3.0 | Sorbic acid | 0.05 | Citric acid | 3.0 | — | — |
| Example 79 | L-Arginine | 1.0 | Tris | 3.0 | Sorbic acid | 0.05 | Citric acid | 3.1 | — | — |
| | | | | | | | Trimellitic | | | |
| | | | | | | | acid | | | |
| | | | | | | | (30:1) | | | |
| Example 80 | L-Arginine | 1.0 | Tris | 3.0 | Sorbic acid | 0.05 | Citric acid | 3.0 | — | — |
| Example 81 | L-Arginine | 1.0 | Tris | 3.0 | Sorbic acid | 0.05 | Citric acid | 3.1 | — | — |
| | | | | | | | Trimellitic | | | |
| | | | | | | | acid | | | |
| | | | | | | | (30:1) | | | |
| Comparative | — | — | Tris | 3.0 | Sorbic acid | 0.05 | Citric acid | 3.0 | — | — |
| Example 1 | | | | | | | | | | |
| Comparative | L-Arginine | 1.0 | — | — | Sorbic acid | 0.05 | Citric acid | 3.0 | Ethylenediamine | 2.0 |
| Example 2 | | | | | | | | | | |
| Comparative | L-Arginine | 1.0 | Tris | 3.0 | — | — | Citric acid | 3.0 | — | — |
| Example 3 | | | | | | | | | | |

TABLE 4

| | | | | | | | | Results | | | | |
|---|---|---|---|---|---|---|---|---|---|---|---|---|
| Table 4 | Treatment liquid | | | | | | | Before dilution | | | After dilution | |
| Continuance | | | | | | pH | | | | W | | W |
| of | pH | | | | | before | pH after | Storage | | anticorrosion | | anticorrosion |
| Table 3 | adjuster | Water | A/B | A/C | B/C | dilution | dilution | stability | Cleanability | properties | Cleanability | properties |
| Example 65 | *1 | Balance | 0.67 | 40.00 | 60.00 | 6.0 | 6.3 | A | A | A | A | A |
| Example 66 | *1 | Balance | 0.67 | 40.00 | 60.00 | 6.0 | 6.4 | A | A | A | A | A |
| Example 67 | *1 | Balance | 0.33 | 100.00 | 300.00 | 6.0 | 6.5 | A | A | A | B | B |
| Example 68 | *1 | Balance | 0.33 | 100.00 | 300.00 | 6.0 | 6.4 | A | A | A | B | B |
| Example 69 | *1 | Balance | 0.20 | 20.00 | 100.00 | 6.0 | 6.3 | A | A | A | B | A |
| Example 70 | *1 | Balance | 0.20 | 20.00 | 100.00 | 6.0 | 6.3 | A | A | A | B | A |
| Example 71 | *1 | Balance | 0.33 | 20.00 | 60.00 | 6.0 | 6.3 | A | A | A | A | B |
| Example 72 | *1 | Balance | 1.00 | 20.00 | 20.00 | 9.0 | 8.3 | A | A | B | A | B |
| Example 73 | *1 | Balance | 0.33 | 20.00 | 60.00 | 6.0 | 6.3 | A | A | A | A | B |
| Example 74 | *1 | Balance | 0.33 | 20.00 | 60.00 | 6.0 | 6.4 | A | A | A | A | B |
| Example 75 | *1 | Balance | 0.33 | 20.00 | 60.00 | 6.0 | 6.3 | A | A | A | B | B |
| Example 76 | *1 | Balance | 0.33 | 20.00 | 60.00 | 6.0 | 6.0 | A | A | A | B | A |
| Example 77 | *1 | Balance | 0.33 | 20.00 | 60.00 | 6.0 | 6.0 | A | A | A | A | A |
| Example 78 | * | Balance | 0.33 | 20.00 | 60.00 | 6.0 | 6.0 | A | A | A | B | A |
| Example 79 | *1 | Balance | 0.33 | 20.00 | 60.00 | 6.0 | 6.0 | A | A | A | A | A |
| Example 80 | *1 | Balance | 0.33 | 20.00 | 60.00 | 6.0 | 6.0 | A | A | A | B | A |
| Example 81 | *1 | Balance | 0.33 | 20.00 | 60.00 | 6.0 | 6.0 | A | A | A | B | A |
| Comparative | *1 | Balance | — | — | — | 7.0 | 6.8 | A | A | E | A | E |
| Example 1 | | | | | | | | | | | | |
| Comparative | *1 | Balance | — | — | — | 6.0 | 6.9 | A | A | E | A | E |
| Example 2 | | | | | | | | | | | | |
| Comparative | *1 | Balance | — | — | — | 6.0 | 6.3 | E | A | A | E | A |
| Example 3 | | | | | | | | | | | | |

From the results shown in the tables, it has been confirmed that the treatment liquid according to the embodiment of the present invention provides a desired effect.

It has been confirmed that in a case where the pH of the treatment liquid is 4.0 to 8.0, the effect of the present invention is further improved (Examples 1 to 9).

It has been confirmed that in a case where the specific compound includes at least one compound selected from the group consisting of arginine, histidine, and lysine, the effect of the present invention is more excellent (Examples 5 and 17 to 20).

It has been confirmed that in a case where the content of the specific compound is 0.2% to 70.0% by mass with respect to the total mass of the components excluding the solvent in the treatment liquid, the effect of the present invention is more excellent (Examples 5 and 10 to 16).

It has been confirmed that in a case where two or more kinds of specific compounds are included, the effect of the present invention is more excellent (Examples 5, 14, 65, and 66).

It was confirmed that in a case where the amino alcohol includes at least one compound selected from the group consisting of Tris, Bis-Tris, Bis-Tris-Propane, 2-amino-1,3-propanediol, and 3-amino-1,2-propanediol, the effect of the present invention is more excellent (Examples 5 and 37 to 42).

It has been confirmed that in a case where the content of the amino alcohol is 2.0% to 72.0% by mass with respect to the total mass of the components excluding the solvent in the treatment liquid, the effect of the present invention is more excellent (Examples 5 and 29 to 36).

It has been confirmed that in a case where two or more kinds of amino alcohols are included, the effect of the present invention is more excellent (Examples 5, 33, 69, and 70).

It has been confirmed that in a case where the antimicrobial agent includes at least one antimicrobial agent selected from the group consisting of benzethonium chloride, a carboxylic acid-based antimicrobial agent, and an isothiazoline-based antimicrobial agent, the effect of the present invention is more excellent (Example 5 and 51 to 64).

It has been confirmed that in a case where the content of the antimicrobial agent is 0.05% to 12.0% by mass with respect to the total mass of the components excluding the solvent in the treatment liquid, the effect of the present invention is more excellent (Examples 5 and 43 to 50).

It has been confirmed that in a case where two or more kinds of antimicrobial agents are included, the effect of the present invention is more excellent (Examples 45, 67, and 68).

It has been confirmed that in a case where the mass ratio of the content of the specific compound to the content of the antimicrobial agent (the content of specific compound/the content of antimicrobial agent) is 1.50 to 60.00, the effect of the present invention is more excellent (Examples 5, 10 to 16, and 43 to 50).

It has been confirmed that in a case where the mass ratio of the content of the amino alcohol to the content of the antimicrobial agent (the content of the amino alcohol/the content of the antimicrobial agent) is 4.00 to 180.00, the effect of the present invention is more excellent (Examples 5, 29 to 36, and 43 to 50).

It was confirmed that in a case where the mass ratio of the content of the specific compound to the content of the amino alcohol (the content of specific compound/the content of amino alcohol) is 0.10 to 6.00, the effect of the present invention is more excellent (Examples 5, 10 to 16, and 29 to 36).

It has been confirmed that in a case where the organic acid includes at least one compound selected from the group consisting of a dicarboxylic acid and a tricarboxylic acid, the effect of the present invention is more excellent (Examples 5 and 24 to 28).

It has been confirmed that in a case where the content of the organic acid is 15.0% to 50.0% by mass with respect to the total mass of the components excluding the solvent in the treatment liquid, the effect of the present invention is more excellent (Examples 5 and 21 to 23).

What is claimed is:

1. A treatment liquid for a semiconductor substrate, comprising:
an amphoteric compound;
an antimicrobial agent; and
an amino alcohol,
wherein the amphoteric compound includes an acid group having a pKa of less than 4.5 and a basic group having a pKa of more than 4.5, and
the number of the basic groups is larger than the number of the acid groups.

2. The treatment liquid for a semiconductor substrate according to claim 1,
wherein the amphoteric compound includes a basic amino acid.

3. The treatment liquid for a semiconductor substrate according to claim 1,
wherein the antimicrobial agent includes at least one or more antimicrobial agents selected from the group consisting of a cationic antimicrobial agent, a carboxylic acid-based antimicrobial agent, a phenolic antimicrobial agent, an isothiazoline-based antimicrobial agent, and an alcoholic antimicrobial agent.

4. The treatment liquid for a semiconductor substrate according to claim 1, further comprising an organic acid.

5. The treatment liquid for a semiconductor substrate according to claim 1,
wherein a pH of the treatment liquid is 4.0 to 8.0.

6. The treatment liquid for a semiconductor substrate according to claim 1,
wherein a mass ratio of a content of the amphoteric compound to a content of the antimicrobial agent is 3.00 to 50.00.

7. The treatment liquid for a semiconductor substrate according to claim 1,
wherein a mass ratio of a content of the amino alcohol to a content of the antimicrobial agent is 10.00 to 150.00.

8. The treatment liquid for a semiconductor substrate according to claim 1,
wherein the treatment liquid for a semiconductor substrate is used for cleaning a semiconductor substrate having tungsten, which has been subjected to a chemical mechanical polishing treatment.
